(19) United States
(12) Patent Application Publication
(10) Pub. No.: US 2021/0211094 A1
(43) Pub. Date: Jul. 8, 2021

(54) METHOD FOR DRIVING ELECTRONIC DEVICE

(71) Applicants: GLOBAL FRONTIER CENTER FOR MULTISCALE ENERGY SYSTEMS, Seoul (KR); SEOUL NATIONAL UNIVERSITY R&DB FOUNDATION, Seoul (KR)

(72) Inventors: Man Soo CHOI, Seoul (KR); Namyoung AHN, Seoul (KR); Kiwan JEONG, Seoul (KR)

(21) Appl. No.: 17/192,052

(22) Filed: Mar. 4, 2021

Related U.S. Application Data
(63) Continuation-in-part of application No. PCT/KR2019/011478, filed on Sep. 5, 2019.

(30) Foreign Application Priority Data
Sep. 5, 2018 (KR) 10-2018-0106094
Sep. 4, 2019 (KR) 10-2019-0109398

(51) Int. Cl. H02S 50/00; H02S 99/00; H03K 3/53

(52) U.S. Cl. CPC H02S 50/00; H03K 3/53; H02S 99/00

(57) ABSTRACT

The present invention provides a method for driving an electronic device so that the electronic device can have higher stability and longer service life. More particularly, proposed is a method for driving an electronic device so that power supply sources including perovskite solar cells, organic solar cells, or the like, or other electronic devices can have higher stability and longer service life.

### CROSS REFERENCE TO RELATED APPLICATIONS

This application is a continuation-in-part of copending PCT Application No. PCT/KR2019/011478 filed Sep. 5, 2019, entitled “Method For Driving Electronic Device”, which claims the benefits of priority to Korean Patent Application No. KR 10-2018-0106094 filed Sep. 5, 2018, and Korean Patent Application No. KR 10-2019-0109398 filed Sep. 4, 2019, all of which are incorporated herein by reference in their entireties for all purposes.

### TECHNICAL FIELD

The present invention relates to a method for driving an electronic device, and more particularly, to a method for driving an electronic device so that power supply sources including perovskite solar cells, organic solar cells, or the like, or other electronic devices can have higher stability and longer service life.

### BACKGROUND

In general, a power transfer method at a maximum efficiency voltage that can be known through the current-voltage characteristics of a solar cell is called maximum power point tracking (MPPT). The inventors of the present invention have found through recent research that when a transfer voltage is applied to a perovskite solar cell, charges trapped at grain boundaries, defect sites, and interfaces accumulate, and at this time, the trapped charges that have accumulated promote an irreversible chemical reaction between the material of a light-absorbing layer and the moisture and oxygen in the air, causing rapid degradation of performance (Refer to “Trapped charge driven degradation of perovskite solar cells,” Mansoo Choi and 8 co-authors, Nov. 10, 2016, and “Atomistic mechanism for trapped-charge driven degradation of perovskite solar cells”, Mansoo Choi and 6 co-authors, Sep. 13, 2017). Further, it has also been reported that when light is given in a perovskite solar cell, the decomposition of materials and deterioration of the device due to ion defects and charged ionic defect state transition is strongly related to trapped charges (Refer to “Controlling competing photochemical reactions stabilizes perovskite solar cells,” 2019, nature photonics, 13, 532-539, Motti and 9 co-authors).

On the other hand, the conventional maximum power point tracking is a method of transferring electric power in a condition that a solar cell can produce the maximum electric power per hour, and has had no difficulty in applying to stable inorganic solar cells. However, if the conventional maximum power point tracking is applied to a perovskite solar cell as it is, charges trapped in a light-absorbing layer continue to accumulate, which promotes an irreversible chemical reaction between the light-absorbing layer and the moisture and oxygen in the air, causing rapid degradation of performance as well as resulting in the degradation of performance due to ion defects. In other words, in the case of organic/inorganic perovskite solar cells on which research has been carried out recently, there are advantages of low cost and good efficiency in electric power generation; however, on the other side, there is a problem that the service life thereof is barely several months at most due to quite low stability.

### SUMMARY OF INVENTION

### Technical Objects

Since power supply sources such as organic/inorganic perovskite solar cells, and the like exhibit service life of several months at most due to their quite low stability, extending the service life of organic/inorganic perovskite solar cells is a challenge that must be resolved for the phase of commercialization that requires a minimum of a unit of a year.

Therefore, in order to commercialize power supply sources such as organic/inorganic perovskite solar cells, and the like, there is a need for a new power transfer method capable of preventing the performance of a device from deteriorating due to the continued accumulation of trapped charges.

In addition, there is a need for a new method for driving an electronic device for securing long-term stability in electronic devices other than organic/inorganic perovskite solar cells.

### Technical Solution

A method for driving a solar cell of the present invention may comprise a driving step in which the solar cell is driven as a power supply source for generating power by exposure while a transfer voltage is applied; and a stabilization step of stabilizing a driving state of the solar cell by controlling the current flowing through the solar cell with stabilization current or controlling the transfer voltage with a stabilization voltage.

In the method for driving a solar cell of the present invention, the stabilization step may be performed during driving of the solar cell, and in the stabilization step, the stabilization voltage or the stabilization current may be applied as a pulsed-voltage or a pulsed-current.

In the method for driving a solar cell of the present invention, the pulsed-voltage or the pulsed-current may be a pulse signal comprising at least one selected from the group consisting of steps, ramps, sine waves, and signals generated through operations thereof.

In the stabilization step of the method for driving a solar cell of the present invention, the pulsed-voltage or the pulsed-current may be applied under a predetermined application condition, and the application condition may comprise one or more of a pulse time interval, a pulse duration, a pulsed-voltage value, a pulsed-current value, and the number of pulse.

In the method for driving a solar cell of the present invention, the stabilization step may comprise a first pulse applying step of applying a pulsed-voltage or a pulsed-current under a first application condition; and a second pulse applying step of applying a pulsed-voltage or a pulsed-current under a second application condition after the first pulse applying step.

In the method for driving a solar cell of the present invention, the stabilization step may comprise a characteristic information obtaining step of obtaining one or more of Isc, Rsh, Rs, i0, mkbT, Voc, Imax, Vmax, Pmax, FF, and Eff as characteristic information of the solar cell; a pulse value calculating step of calculating a pulsed-voltage value or a pulsed-current value based on the characteristic information; and a pulse applying step of applying a pulsed-voltage or a pulsed-current with the pulsed-voltage value or the pulsed-current value.

In the method for driving a solar cell of the present invention, in the pulse applying step the pulsed-voltage may be applied to the solar cell, and in the pulse value calculating step the pulsed-voltage may be calculated by Equation 1 below.

Vp=−r×Isc×Rs, [Equation 1]

wherein Vp is a pulsed-voltage, r is a constant of 0.9 to 2, Isc is a short-circuit current of the solar cell, and Rs is a series resistance of the solar cell.

In the method for driving a solar cell of the present invention, in the pulse applying step the pulsed-voltage may be applied to the solar cell, and in the pulse value calculating step the pulsed-voltage may be calculated by Equation 2 below.

Vp=−r×Voc, [Equation 2]

wherein Vp is a pulsed-voltage, r is a constant of 0.1 to 0.3, and Voc is an open-circuit voltage of the solar cell.

In the method for driving a solar cell of the present invention, in the pulse applying step the pulsed-voltage may be applied to the solar cell, and in the pulse value calculating step the pulsed-voltage may be calculated by Equation 3 below.

Vp=r×Voc, [Equation 3]

wherein Vp is a pulsed-voltage, r is a constant of 1 to 1.2, and Voc is an open-circuit voltage of the solar cell.

In the method for driving a solar cell of the present invention, in the pulse applying step the pulsed-voltage may be applied to the solar cell, in the characteristic information obtaining step a current-voltage characteristic curve for the solar cell may be obtained, and in the pulse value calculating step a reference current value may be calculated by Equation 4 below and a voltage value corresponding to the reference current value on the current-voltage characteristic curve may be used as the pulsed-voltage value.

Icr=Isc×r, [Equation 4]

wherein Icr is a reference current, r is a constant of −1 to −0.92 or 0 to 0.2, and Isc is a short-circuit current of the solar cell.

In the method for driving a solar cell of the present invention, in the pulse applying step the pulsed-current may be applied to the solar cell and the pulsed-current may be calculated by Equation 5 below.

Ip=Isc×r, [Equation 5]

wherein Ip is a pulsed-current, r is a constant of −1 to −0.92 or 0 to 0.2, and Isc is a short-circuit current of the solar cell.

The method for driving a solar cell of the present invention may further comprise calculating an error rate c by Equation 6 below, after the stabilization step:

ε=100×((Ids−Iout)/(Ids)), [Equation 6]

wherein Iout is a current value output from the solar cell to which the pulsed-voltage is applied, and Ids is a target current value.

The method for driving a solar cell of the present invention may further comprise a pulse re-applying step of terminating the application of the pulsed-voltage or the pulsed-current or changing an application condition for applying the pulsed-voltage or the pulsed-current, based on the error rate ε.

In the method for driving a solar cell of the present invention, the stabilization step may be performed during driving of the solar cell, and in the stabilization step the stabilization voltage or the stabilization current may be applied as a load voltage or a load current, and the stabilization step may comprise a characteristic information obtaining step of obtaining one or more of Isc, Rsh, Rs, i0, mkbT, Voc, Imax, Vmax, Pmax, FF, and Eff as characteristic information of the solar cell; a load value calculating step of calculating a load voltage value or a load current value based on the characteristic information; and a load applying step of applying the load voltage or the load current with the load voltage value or the load current value.

In the method for driving a solar cell of the present invention, in the load applying step the load voltage may be applied to the solar cell, in the characteristic information obtaining step a current-voltage characteristic curve for the solar cell may be obtained, and in the load value calculating step a reference current value may be calculated by Equation 4 above and a voltage value corresponding to the reference current value on the current-voltage characteristic curve may be used as the load voltage value. At this time, r is a constant of −1 to −0.92, and Isc is a short-circuit current of the solar cell.

In the method for driving a solar cell of the present invention, in the load applying step the load current may be applied to the solar cell, and the load current may be calculated by Equation 9 below.

Iw=Isc×r, [Equation 9]

wherein Iw is a load current, r is a constant of −1 to −0.92, and Isc is a short-circuit current of the solar cell.

In the method for driving a solar cell of the present invention, in the stabilization step the stabilization voltage or the stabilization current may be applied as a pulsed-voltage or a pulsed-current, the stabilization step may comprise a characteristic information obtaining step of obtaining characteristic information of the solar cell; a pulse value calculating step of calculating a pulsed-voltage value or a pulsed-current value based on the characteristic information; and a pulse applying step of applying the pulsed-voltage or the pulsed-current with the pulsed-voltage value or the pulsed-current value, and the characteristic information obtaining step may be performed during driving of the solar cell and the pulse applying step may be performed after the driving of the solar cell is terminated.

### Effects of the Invention

According to the prevent invention, by applying a specific voltage and current during power transfer, under a power transfer condition, or after completion of power transfer, for stabilizing of power supply source, there are provided advantages of preventing accumulation of charge inside the device to suppress a chemical reaction between a light-absorbing layer and moisture and oxygen in the air and preventing performance degradation caused by ion defects and ion migration, thereby increasing a service life, which is beyond a simple principle of extending service life through periodic rests by such a power transfer method.

Since the method for driving an electronic device of the present invention effectively extracts electrons and holes accumulated inside the device, it is possible to prevent electrons and holes from accumulating inside the device and from shortening the service life of the device.

Furthermore, the present invention can provide a method for driving an electronic device capable of increasing the service life and securing the long-term stability of electronic devices, such as an organic thin-film transistor (OTFT), an organic light-emitting diode (OLED), an organic sensor, an organic memory device, and so on.

In particular, as with concentrator photovoltaic (CPV) systems, when the concentrated light of strong intensity is incident on a device to thereby accelerate the generation of electrons and holes inside the device, the method for driving an electronic device of the present invention can effectively improve the performance and service life of the device.

### BRIEF DESCRIPTION OF THE DRAWINGS

FIG. 1 shows an electric circuit model of a power supply source (e.g., a solar cell) 100 out of electronic devices applicable to the present invention;

FIG. 2 shows a current-voltage characteristic curve and an output voltage characteristic curve of a power supply source (e.g., a solar cell) 100 applicable to the present invention;

FIG. 3 shows a graph of a voltage value at a maximum power point and stabilization voltages when pulsed-voltages are applied in accordance with an embodiment of the present invention;

FIG. 4 shows a schematically enlarged scaled graph of a case where a forward bias pulsed-voltage is applied in the graph of FIG. 3, and a current graph corresponding thereto;

FIG. 5 shows examples of pulses applicable to the present invention;

FIG. 6 shows differences in electric current and maximum power according to the presence/absence of pulses while driving a perovskite solar cell in a case of a transfer voltage of 0;

FIG. 7 shows initial current-voltage characteristic curves of experimental devices;

FIG. 8 is a graph comparing normalized maximum power for the cases where no pulse was applied and where a reverse pulse was applied;

FIG. 9 is a graph showing parameters for calculating a pulsed-voltage in accordance with an embodiment;

FIG. 10 is a graph comparing normalized efficiency between an electronic device to which a pulsed-voltage calculated with the parameters of the graph in FIG. 9 was applied and an electronic device operating only in the maximum power point tracking (MPPT) method;

FIG. 11 is a graph showing parameters for calculating a pulsed-voltage in accordance with another embodiment;

FIG. 12 is a graph comparing efficiency between an electronic device to which a pulsed-voltage calculated with the parameters of the graph in FIG. 11 was applied and an electronic device operating only in the MPPT method.

FIG. 13 is a graph showing parameters for calculating a pulsed-voltage in accordance with another embodiment;

FIG. 14 is a graph comparing the efficiency of electronic devices in a case where a pulsed-voltage calculated with the parameters of the graph in FIG. 13 was applied to an electronic device under an open-circuit (OC) condition and in a case where the pulsed-voltage was not applied;

FIG. 15 is a graph showing parameters for calculating a pulsed-current in accordance with another embodiment;

FIG. 16 is a graph comparing the normalized efficiency of electronic devices according to whether or not a pulsed-voltage calculated with the parameters of the graph in FIG. 9 was applied;

FIGS. 17A to 17F are graphs showing changes in normalized power before and after applying pulses under the conditions of FIG. 16;

FIG. 18 is a graph in which the total transfer energy under the pulse conditions of FIG. 16 is normalized and compared with the transfer energy by the MPPT method;

FIG. 19 is a graph comparing normalized efficiency of an electronic device over time according to whether or not a pulsed-voltage calculated with parameters of the graph of FIG. 9 was applied.

FIG. 20 is a graph in which the total transfer energy under the pulse conditions of FIG. 19 is normalized and compared with the transfer energy by the MPPT method over time;

FIG. 21 is a graph comparing normalized efficiency of an electronic device over time according to whether or not a pulsed-voltage calculated with parameters of the graph of FIG. 9 was applied and according to a combination of pulse conditions.

FIG. 22 is a graph in which the total transfer energy under the pulse conditions of FIG. 21 is normalized and compared with the transfer energy by the MPPT method over time;

FIG. 23 is a graph showing a current-voltage characteristic curve obtained in a characteristic information obtaining step when a load voltage is applied to a solar cell in a load applying step.

FIG. 24 is a graph showing a transfer power for each of two solar cells to which load voltages are applied at three points P1, P2, and P3 shown in FIG. 23, respectively.

FIG. 25 is a graph showing a total work for each of two solar cells to which load voltages are applied at three points P1, P2, and P3 shown in FIG. 23, respectively.

FIG. 26 is a graph showing a total gain obtained by comparing total works of two solar cells to which load voltages are applied at three points P1, P2, and P3 shown in FIG. 23, respectively.

### DETAILED DESCRIPTION OF EMBODIMENTS

Hereinafter, a method for transferring electric power to and from a solar cell in accordance with an embodiment of the present invention will be described in detail. The accompanying drawings illustrate exemplary forms of the present invention and are only provided to describe the present invention in greater detail, and the scope of the present invention is not limited thereby.

In addition, the same or equivalent components are assigned the same reference numerals regardless of the drawings and description thereof will not be repeated, and the size and shape of respective components shown may be scaled up or down for the sake of convenience of description.

In the method for driving an electronic device of the present invention, the electronic device may be a solar cell. That is, the method for driving the electronic device of the present invention may be a method for driving a solar cell.

A method for driving a solar cell in accordance with the present invention comprises:

a driving step (S10) in which the solar cell is driven as a power supply source for generating power by exposure while a transfer voltage is applied; and

a stabilization step (S20) of stabilizing a driving state of the solar cell by controlling the current flowing through the solar cell with a stabilization current or controlling the transfer voltage with a stabilization voltage.

The method for driving a solar cell of the present invention may be applied to other electronic device than a solar cell, wherein the electronic device may be at least one selected from the group consisting of an organic thin-film transistor (OTFT), an organic light-emitting diode (OLED), an organic sensor, an organic memory device and so on. The method for driving a solar cell of the present invention can be expected to have a more dramatic effect in stabilizing the perovskite solar cells.

In the driving step of the solar cell (S10), the driving of the solar cell may be that the solar cell is driven as a power supply source 100 that generates power by irradiating light to the solar cell.

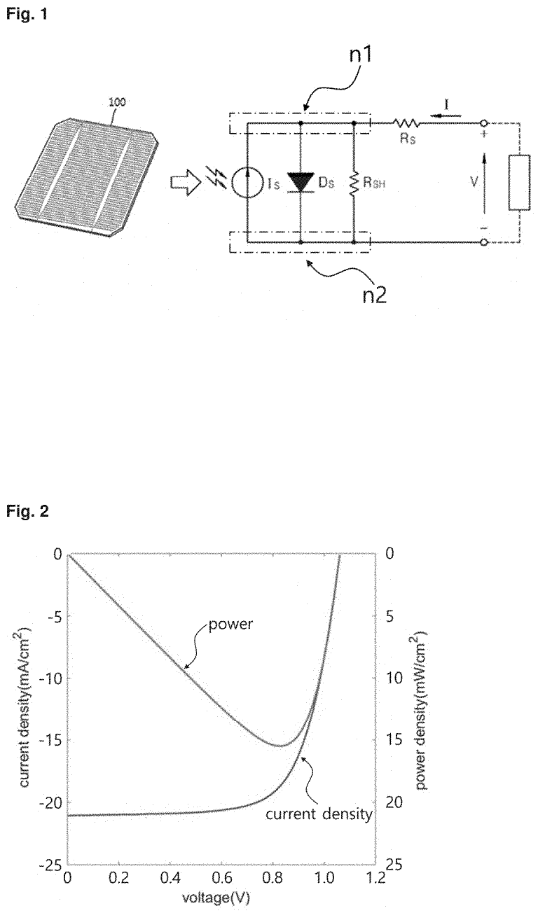

FIG. 1 shows an electric circuit model (equivalent circuit) of a power supply source (e.g., a solar cell) 100 out of electronic devices applicable to the present invention. Referring to FIG. 1, the electric circuit model of the power supply source (e.g., a solar cell) 100 may consist of a current source Is, a diode Ds, and resistances Rs and Rsh.

Specifically, in the method for driving a solar cell of the present invention, the equivalent circuit of the solar cell may comprise a current source Is, a diode Ds, a short-circuit resistance Rsh, and a series resistance Rs. Both ends of each of the current source Is, the diode Ds and the short-circuit resistance Rsh may be connected to a first node n1 and a second node n2, in parallel. The diode Ds may be connected such that a current flowing from the first node n1 through the diode Ds to the second node n2 is in a forward direction. A positive terminal (+) may be connected to the first node n1, and a negative terminal (−) may be connected to the second node n2. The series resistance Rs may be located between the first node n1 and the positive terminal (+).

When a transfer voltage is applied to the positive terminal (+) and the negative terminal (−), the solar cell can be driven as a power driving source, and the solar cell can generate electric power according to the light irradiated to the solar cell.

In the method for driving a solar cell of the present invention, when the transfer voltage or the stabilization voltage (pulsed-voltage or load voltage) described later is applied to the solar cell such that the potential of the positive terminal (+) is greater than the potential of the negative terminal (−), the transfer voltage or the stabilization voltage may be greater than 0. When the transfer voltage or stabilization voltage is applied to the solar cell such that the potential of the positive terminal (+) is lower than the potential of the negative terminal (−), the transfer voltage or the stabilization voltage may be less than 0.

In the method for driving a solar cell of the present invention, the stabilization current (pulsed-current or load current) described later may be greater than 0 when flowing from the positive terminal (+) through the solar cell to the negative terminal (−), and it may be less than 0 when flowing in the opposite direction. In the case of photocurrent, it is defined as a value having an opposite sign to the current.

That is, in the equivalent circuit shown in FIG. 1, the transfer voltage, the stabilization voltage, and the stabilization current may be positive values when applied in the same direction as the arrows of I and V, and the transfer voltage, the stabilization voltage, and the stabilization current may be negative values when applied in the opposite direction. The power generated in the electric circuit model (equivalent circuit) of the solar cell can be known from the voltage V and the current I generated in the electric circuit model of the solar cell.

The power supply source (e.g., a solar cell) 100 has a current-voltage characteristic curve and a power-voltage characteristic curve as shown in FIG. 2, and if the power supply source 100 has non-linear characteristics as in such a solar cell, the electric power generated from the power supply source 100 is monitored in order to extract the maximum power from the power supply source 100, thereby transferring the electric power at a maximum power point. A method of transferring power at a maximum power point that can be known through the current-voltage characteristics of a solar cell is called maximum power point tracking (MPPT).

In the driving step of the solar cell (S10) of the method for driving a solar cell of the present invention, a transfer voltage may be applied to the solar cell as a voltage at a maximum power point. That is, in the driving step of the solar cell (S10) of the method for driving a solar cell of the present invention, the solar cell may be driven according to the maximum power point tracking (MPPT).

However, if electric power is continuously transferred at the maximum power point, charges trapped in a light-absorbing layer continue to accumulate, which promotes an irreversible chemical reaction between the light-absorbing layer and the moisture and oxygen in the air, causing rapid degradation of performance.

Accordingly, the present invention comprises a stabilization step (S20) of applying a stabilization voltage or a stabilization current to the electronic device.

In one embodiment, the stabilization step (S20) may be performed during driving of the solar cell. That the stabilization step (S20) is performed during driving of the solar cell may mean that the stabilization step (S20) is performed in a state in which a photocurrent is generated as the solar cell is exposed.

As shown in FIG. 4, in the stabilization step (S20), the stabilization voltage or the stabilization current may be applied as a pulsed-voltage or a pulsed-current. That is, the stabilization voltage and the stabilization current can be applied in the form of a pulse.

In the stabilization step (S20), the pulsed-voltage or the pulsed-current is applied under a predetermined application condition, and the application condition may comprise one or more of a pulse time interval (pulse period), a pulse duration, a pulsed-voltage value, a pulsed-current value, a pulse application time, and the number of pulse.

The pulse time interval Tw refers to the elapsed time from the beginning of one pulse to the beginning of the next pulse when the pulse is repeatedly applied at a predetermined time interval.

The pulse duration Tp refers to a pulse width.

The pulsed-voltage value or pulsed-current value refers to a pulse amplitude.

The number of pulse refers to the number of times a pulse is applied.

The pulse application time refers to the elapsed time from the application of the first pulse to the application of the last pulse. For example, if the number of pulse is N, the pulse application time may be N*(T_{W}+T_{P}).

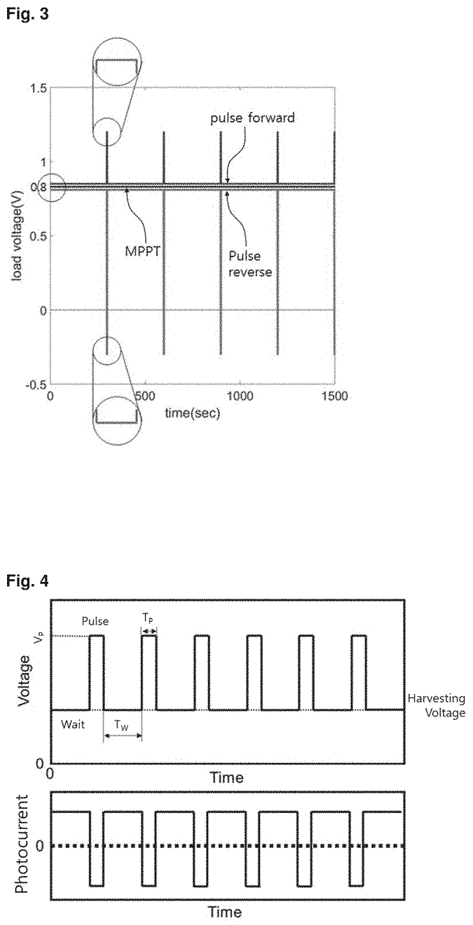

According to the present invention, a bias voltage applied to the power supply source 100 may be implemented in a method of applying a pulsed-voltage or a pulsed-current. FIG. 3 is a graph showing a voltage value at a maximum power point (MPPT), and a forward bias pulsed-voltage and a reverse bias pulsed-voltage to be applied to change the voltage value at the maximum power point.

Specifically, the forward bias pulsed-voltage refers to a case where a pulsed-voltage that applies a voltage greater than the voltage at the maximum power point is applied. The reverse bias pulsed-voltage refers to a case where a pulsed-voltage that applies a voltage in the direction of the photocurrent of the power supply source 100 is applied. FIG. 4 shows a schematically enlarged scaled graph of a case where a forward bias pulsed-voltage is applied in the graph of FIG. 3, and a current graph corresponding thereto.

However, the present invention is not limited to what is described above, it may be possible to apply a pulse signal comprising at least one selected from the group consisting of steps, ramps, sine waves, and signals generated through operations thereof, and the like, from simple pulses such as a forward pulse that applies a voltage greater than that in the maximum power point or a reverse pulse that applies a voltage in the direction of the photocurrent of the solar cell, and the like, to highly designed pulses with devices taken into account.

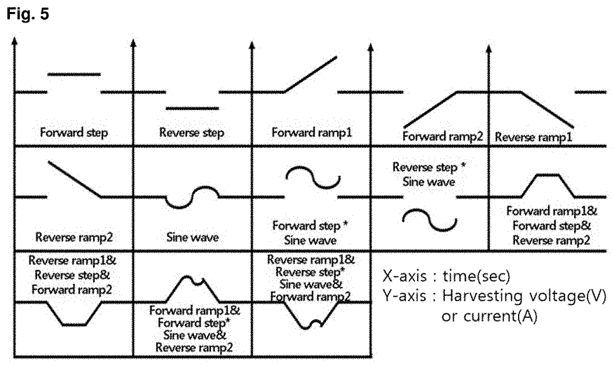

FIG. 5 shows examples of pulses applicable to the present invention. Examples of pulse signals such as a forward step, a reverse step, ramp 1, ramp 2, a sine wave, and so on are shown, and all forms that can be generated through operation symbols such as “&,” “*,” or the like may be the pulses that can be applied to the present invention. Moreover, in the case of a sine wave, various sine wave pulses implemented by modifying values such as frequency, phase, and so on may be applied.

On the other hand, as described above, when a voltage is applied to a perovskite solar cell, charges trapped at grain boundaries, defect sites, and interfaces accumulate, and at this time, the trapped charges that have accumulated promote an irreversible chemical reaction between the material of a light-absorbing layer and the moisture and oxygen in the air, thereby becoming a cause for a performance decrease resulting from ion defects and migration; however, according to the present invention, these charges can be detrapped from the accumulated state through appropriate electrical pulses.

According to the present invention, the electronic device (e.g., the power supply source 100) may be connected to a control circuit (not shown) that can apply a pulse circuit as a bias voltage.

Further, according to the present invention, the stabilization step (S20) may comprise applying the pulsed-voltage or the pulsed-current at a predetermined time interval. In other words, it is possible to apply a pulse signal capable of stabilizing the power supply source 100 at a predetermined time interval, during transferring electric power from a perovskite solar cell by the conventional maximum power point tracking method. The predetermined time interval may be, for example, 0.1 second to 1 second.

In addition, according to the present invention, in the stabilization step (S20) the pulsed-voltage or the pulsed-current may be applied when a predetermined condition is satisfied. When a condition such as a decrease in efficiency, or the like, besides the effect of temperature, for example, is satisfied as the predetermined condition, the pulsed-voltage or the pulsed-current may be applied. For example, since the pattern of performance change of the solar cell varies according to efficiency decrease sections, it is possible to apply the most suitable pulsed-voltage or pulsed-current according to the predetermined condition. More specifically, different optimized pulses may be applied before the performance decrease of the device starts to appear, at an initial section of the performance decrease, and at a section where the performance decrease has considerably progressed.

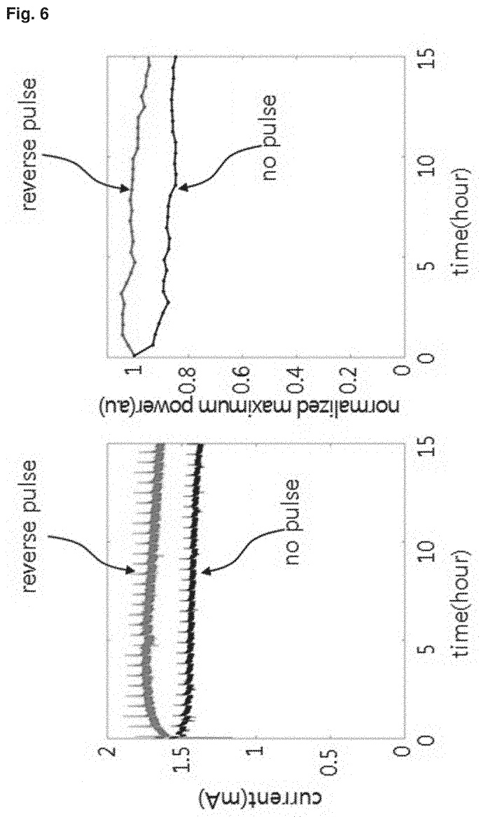

FIG. 6 shows differences in electric current and maximum power according to the presence/absence of pulses while driving a perovskite solar cell at a transfer voltage of=0, which are the results obtained by measuring the current-voltage curves at an interval of 30 minutes. It can be seen from FIG. 6 that the case where the pulse was applied has longer service life than the case where the pulse was not applied.

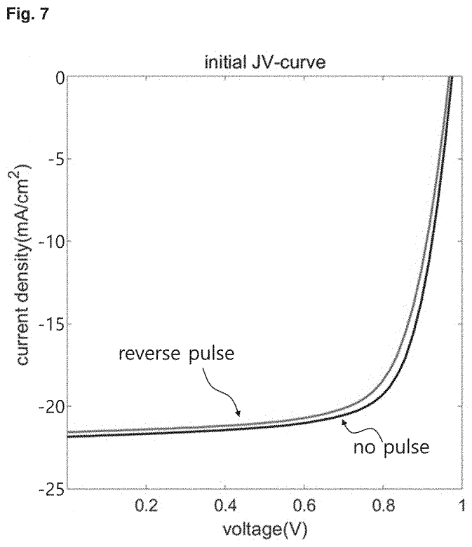

FIG. 7 is initial current-voltage characteristic curves of experimental devices, and it can be seen that the initial performance of the two devices was the same. As the experimental device of FIG. 7, for example, a perovskite solar cell made in a planar junction structure in the order of indium tin oxide, fullerene, a perovskite light-absorbing layer (CH₃NH₃PbI₃), spiro-MeOTAD, and a gold electrode (Au) was used. It can be seen from FIG. 7 that the cause that the device to which the reverse pulsed-voltage was applied has longer service life than the device to which the pulsed-voltage was not applied has not resulted from the difference in the initial state.

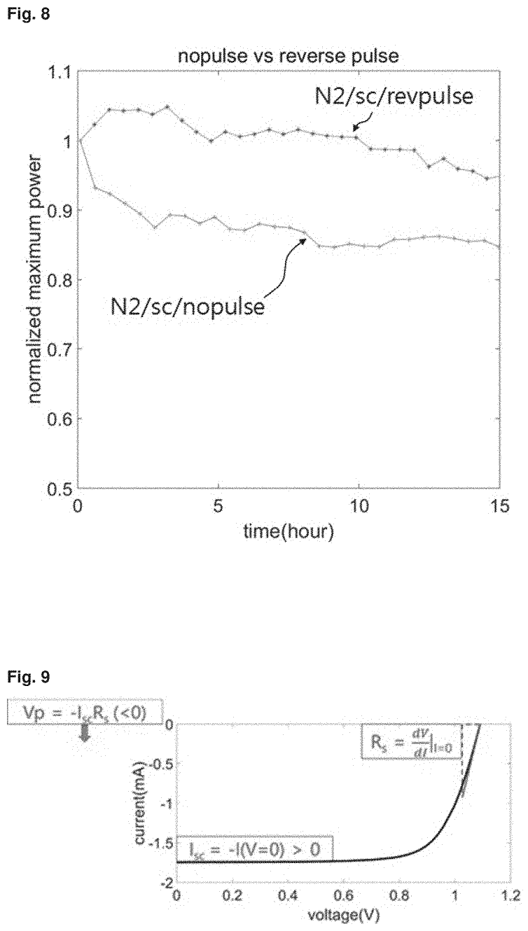

FIG. 8 is a graph comparing normalized maximum power for the cases where no pulse was applied (N2/sc/nopulse) and where a reverse pulse was applied (N2/sc/revpulse).

In one embodiment, the stabilization step of the method for driving a solar cell of the present invention may comprise a characteristic information obtaining step of obtaining characteristic information of the solar cell; a pulse value calculating step of calculating a pulsed-voltage value or a pulsed-current value based on the characteristic information; and a pulse applying step of applying the pulsed-voltage or the pulsed-current with the pulsed-voltage value or the pulsed-current value.

In the characteristic information obtaining step, the characteristic information may comprise one or more of Isc, Rsh, Rs, i0, mkbT, Voc, Imax, Vmax, Pmax, FF, and Eff. The characteristic information indicates only the magnitude and can be expressed only as a positive number. For example, Isc is a negative number in FIG. 2 or FIG. 7, but it may be obtained as a positive number by taking the absolute value of the negative number.

Isc is a short-circuit current of the electronic device and is a magnitude of the current value when the voltage of the electronic device is 0. Rsh is a short-circuit resistance of the electronic device. Rs is a series resistance of the electronic device. i0 is a reverse saturation current. mkbT is a characteristic coefficient of the electronic device taking into account thermal fluctuation (KbT) and statistical characteristics (m) of the electronic device. Voc is an open-circuit voltage of the electronic device and is a voltage value when the current of the electronic device is zero. Imax is a magnitude of the current value at the maximum power point. Vmax is a voltage value at the maximum power point. Pmax is an electric power value at the maximum power point.

FF is a value obtained by dividing the product of a current density and a voltage value (Vmax×Imax) at the maximum power point by the product of Voc and Isc.

Eff is a drive efficiency of the device, and can be calculated, for example, as a value of the product of Isc, Voc, and FF per device area (Eff=(Isc×Voc×FF)/(unit area)).

In the characteristic information obtaining step, the characteristic information of the electronic device may be measured through jv sweeps. The jv sweep may be to obtain a j−v curve by measuring electric current while applying a specific voltage to learn the drive characteristics of the electronic device. j may be a surface current density, and v may be a voltage.

The characteristic information may be measured through operations based on a finite number of jv values. The jv values may be selected out of values from a voltage 0.3 V lower than the driving voltage to a voltage 0.3 V higher than the driving voltage (transfer voltage). Preferably, the jv values may be selected out of values from a voltage 0.2 V lower than the driving voltage to a voltage 0.2 V higher than the driving voltage. The jv values may be a voltage value applied to the electronic device to measure the surface current density in order to learn the driving characteristics of the electronic device. The driving voltage may be a voltage applied to the electronic device to operate the electronic device.

Some of the finite number of jv values may be selected from previously measured characteristic information of the electronic device. In other words, parameters for measurement when measuring the electronic device may be obtained based on the measurement information of the electronic device that was measured previously. Specifically, electric power may be extracted at a maximum power point based on the previously measured characteristic information of the electronic device.

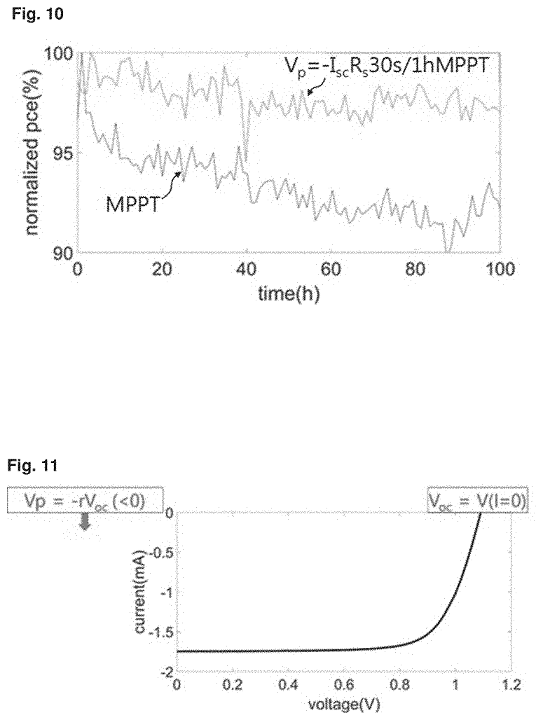

In the pulse applying step, the pulsed-voltage may be applied to the solar cell. FIG. 9 is a graph showing parameters for calculating a pulsed-voltage in accordance with an embodiment, and FIG. 10 is a graph comparing efficiency between an electronic device to which a pulsed-voltage calculated with the parameters of the graph in FIG. 9 was applied and an electronic device operating only in the MPPT method. As an embodiment, the pulsed-voltage Vp may be the product of a short-circuit current Isc and a series resistance Rs inside the electronic device. More specifically, it may be a reverse bias pulsed-voltage with a negative sign on the product of the two parameters. The pulsed-voltage can be calculated by Equation 1 below.

Vp=−r×Isc×Rs [Equation 1]

Isc is a short-circuit current and refers to a magnitude of the current value flowing through the conductor when the voltage difference between both ends of the electronic device is 0. Rs is a series resistance value inside the electronic device, and may be a value obtained by differentiating the voltage with respect to the current when the current is 0. r may be a constant specified at the time of driving. In Equation 1, r may be a constant of 0.9 to 2. For example, r may be 1. In Equation 1, the pulsed-voltage is calculated based on the short-circuit current Isc, and may have an ideal value when r is 1. However, r may be selected from values from 0.9 to 2 in consideration of a measurement error in the process of obtaining characteristic information, properties of materials such as a charge transfer layer and a light absorption layer of a solar cell, and so on.

For example, when Rs is 70 ohms and Isc is 1.8 mA, the pulsed-voltage Vp may be −0.126 V, as shown in FIG. 9.

FIG. 10 is a graph showing data obtained by experimenting with ITO/SnO2/(FAI) 0.9 (MABr) 0.1PbI2/Spiro-MeOTAD/Au (Glass encap) device, and plotted by comparing the efficiency (pce) values obtained by performing jv-sweeps at an interval of 1 hour with their initial values. The graph in FIG. 10 shows that the service life has improved in the case where the pulsed-voltage Vp was applied to the electronic device for 30 seconds at an interval of 1 hour compared to the case of the electronic device operating only in the MPPT method. The case of the electronic device driven only in the MPPT method showed an efficiency decrease by about 5% per 100 hours, which indicated an efficiency decrease by about 1% per 100 hours than that of the device driven by the method for driving an electronic device of the present invention.

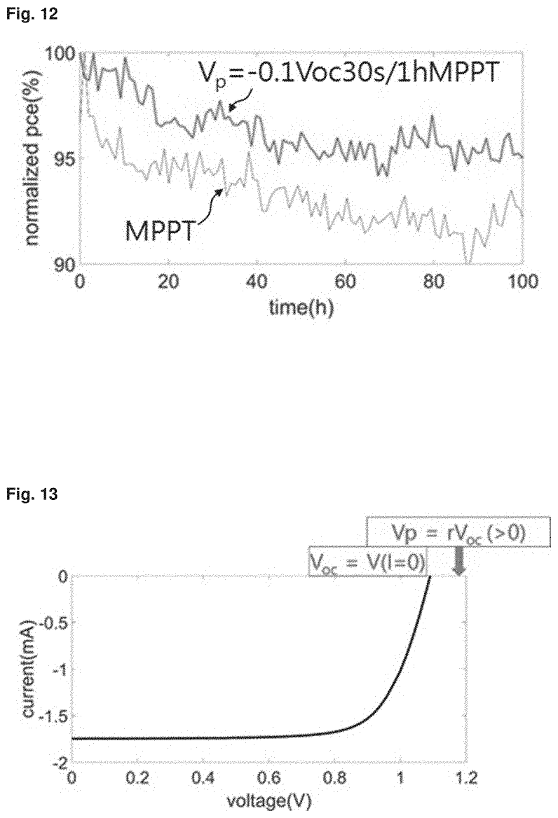

FIG. 11 is a graph showing parameters for calculating a pulsed-voltage in accordance with another embodiment, and FIG. 12 is a graph comparing efficiency between an electronic device to which a pulsed-voltage calculated with the parameters of the graph in FIG. 11 was applied and an electronic device operating only in the MPPT method. As another embodiment, the pulsed-voltage Vp may be the product of an open-circuit voltage Voc and a constant r. More specifically, it may be a reverse bias pulsed-voltage with a negative sign on the product of the two parameters. The pulsed-voltage can be calculated by Equation 2 below.

Vp=−r×Voc [Equation 2]

Voc may be an open-circuit voltage, which may be a voltage across both ends of the electronic device when the current flowing through the electronic device is zero. r may be a constant specified at the time of driving. In Equation 2, r may be a constant of 0.1 to 0.3. For example, r may be 0.2. In Equation 2, the pulsed-voltage is expressed as Voc, and in Equation 2, the value of r may be determined in consideration of the correlation between the short-circuit current Isc and the open-circuit voltage Voc.

For example, when Voc is 1.1 V and r is 0.1, Vp may be −0.11 V, as shown in FIG. 11. FIG. 12 is a graph showing data obtained by experimenting with ITO/SnO2/(FAI) 0.9 (MABr) 0.1PbI2/Spiro-MeOTAD/Au (Glass encap) device and plotted by comparing the efficiency (pce) values obtained by performing jv-sweeps at an interval of 1 hour with their initial values. The graph in FIG. 12 shows that the service life has improved in the case where the pulsed-voltage Vp was applied to the electronic device for 30 seconds at an interval of 1 hour compared to the case of the device operating only in the MPPT method. The case of the electronic device driven only in the MPPT method showed an efficiency decrease by about 5% per 100 hours, which indicated an efficiency decrease by about 3% per 100 hours than that of the device driven by the method for driving an electronic device of the present invention.

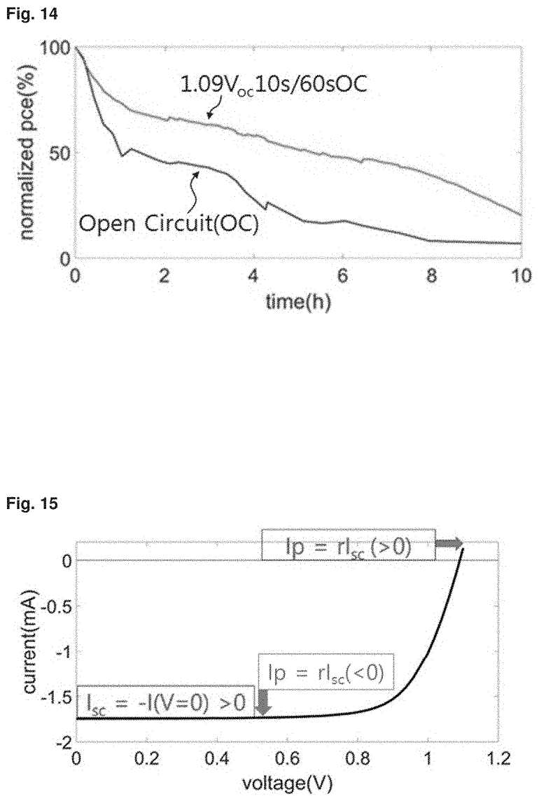

FIG. 13 is a graph showing parameters for calculating a pulsed-voltage in accordance with another embodiment, and FIG. 14 is a graph comparing the efficiency of electronic devices in a case where a pulsed-voltage calculated with the parameters of the graph in FIG. 13 was applied to an electronic device under an OC condition and in a case where the pulsed-voltage was not applied. As another embodiment, the pulsed-voltage Vp may be the product of an open-circuit voltage Voc and a constant r, being a forward bias pulsed-voltage. The pulsed-voltage can be calculated by Equation 3 below.

Vp=r×Voc [Equation 3]

Voc may be an open-circuit voltage, which may be a voltage across both ends of the electronic device when the current flowing through the electronic device is zero. r may be a constant specified at the time of driving. In Equation 3, r may be a constant of 1 to 1.2. For example, r may be 1. For example, when Voc is 1 V and r is 1.09, Vp may be 1.09 V, as shown in FIG. 13. Equation 3 means applying a pulsed-voltage with a value greater than Voc. However, since an excessively large voltage may damage the solar cell, r in Equation 3 may be selected from values from 1 to 1.2.

FIG. 14 is a graph showing data obtained by experimenting with ITO/C60/MAPbI3/Spiro-MeOTAD/Au device and plotted by comparing the efficiency (pce) values obtained by performing jv-sweeps at an interval of 10 minutes on the continuously exposed electronic device under 1 sun condition with their initial values. The graph in FIG. 14 shows that the service life has improved when the pulsed-voltage Vp was applied for 60 seconds at an interval of 1 minute, as compared with the case under the OC condition only.

In the characteristic information obtaining step a current-voltage characteristic curve for the solar cell may be obtained, and in the load value calculating step a reference current value may be calculated by Equation 4 and a voltage value corresponding to the reference current value on the current-voltage characteristic curve may be used as the pulsed-voltage value.

Icr=Isc×r, [Equation 4]

wherein Icr is a reference current, r is a constant of −1 to −0.92 or 0 to 0.2, and Isc is a short-circuit current of the solar cell. For example, r may be −1 or 0.1.

In the pulse applying step, the pulsed-current may be applied to the solar cell.

FIG. 15 is a graph showing parameters for calculating a pulsed-current in accordance with another embodiment. As another embodiment, the pulsed-current Ip, which is the product of a short-circuit current Isc and a constant r, may be a forward bias pulsed-current. The pulsed-current can be calculated by Equation 5 below.

Ip=Isc×r [Equation 5]

Isc is a magnitude of the current value flowing through the conductor when the voltage difference between both ends of the electronic device is 0. In Equation 5, r may be a constant value of −1 to −0.92 or 0 to 0.2. For example, r may be −1 or 0.1. For example, when Isc is 1.8 mA and r is 0.1, the pulsed-current Ip may be 0.18 mA, as illustrated in FIG. 15. Further, when r is −0.92, the pulsed-current Ip may be −1.71 mA.

The pulsed-voltage obtained by Equation 1, the pulsed-voltage obtained by Equation 2, the pulsed-voltage obtained by applying the value of r of −1 to −0.92 to Equation 4, and the pulsed-current obtained by applying the value of r of −1 to −0.92 to Equation 5 may be taken into account charge extraction and ionic polarization relaxation.

In the case of (applying voltage in a forward direction including) driving at the maximum power point, charges are accumulated inside the device, which may cause deterioration of the device. This charge accumulation may be exhibited as the first node n1 having a higher potential than the second node n2 from the viewpoint of the steady-state equivalent circuit model of FIG. 1.

The charge accumulation may be eliminated by reducing a potential difference between the first node n1 and the second node n2.

Referring to FIG. 9, when r is 1 in Equation 1, the pulsed-voltage may make the potentials of the first node n1 and the second node n2 the same in the equivalent circuit model.

In Equation 2, the range of r may be taken into account that the pulsed-voltage capable of making the potentials of the first node n1 and the second node n2 the same is approximately −0.2 times the value of Voc.

In Equations 4 and 5, the range of r may be taken into account that charge extraction is possible when the photocurrent value is similar to −Isc, even if the pulsed-voltage obtained by Equation 1 is not applied.

In the case of (applying voltage in a forward direction including) driving at the maximum power point, ionic polarization may occur due to the forward electric field inside the light absorption layer.

This phenomenon temporarily aids in charge extraction due to the screening effect, but may cause deterioration of the device in the long term.

The pulsed-voltage obtained by Equation 1, the pulsed-voltage obtained by Equation 2, the pulsed-voltage obtained by applying the value of r of −1 to −0.92 to Equation 4, and the pulsed-current obtained by applying the value of r of −1 to −0.92 to Equation 5 are smaller than (the driving voltage including) the maximum power voltage, which means that the electric field inside the light absorbing layer is smaller, resulting in that the effect of reducing ionic polarization due to the forward electric field at (the driving voltage including) the maximum power voltage can also be expected.

The pulsed-voltage obtained by Equation 3, the pulsed-voltage obtained by applying the value of r of 0 to 0.2 to Equation 4, and the pulsed-current obtained by applying the value of r of 0 to 0.2 to Equation 5 may be taken into account charge recombination and ion screening.

In the case of (the application of a forward voltage including) driving at the maximum power point, charges accumulate inside the device, which may cause device deterioration.

The pulsed-voltage obtained by Equation 3, the pulsed-voltage obtained by applying the value of r of 0 to 0.2 to Equation 4, and the pulsed-current obtained by applying the value of r of 0 to 0.2 to Equation 5 are intended to remove the accumulated charges, which can be achieved by instantaneous charge injection.

Equation 3 means that the pulsed-voltage is greater than Voc, which may be taken into account that the pulsed-voltage is at the boundary between charge injection and charge extraction.

The pulsed-voltage obtained by applying the value of r of 0 to 0.2 to Equation 4 and the pulsed-current obtained by applying the value of r of 0 to 0.2 to Equation 5 may be taken into account that the the pulsed-voltage obtained by Equation 3 is approximately 0.1 times the Isc value.

In the case of (the application of a forward voltage including) driving at the maximum power point, ionic polarization may occur due to a forward electric field inside the light absorption layer.

This can temporarily facilitate charge extraction by the screening effect. The pulsed-voltage by Equation 3, the pulsed-voltage obtained by applying the value of r of 0 to 0.2 to Equation 4 and the pulsed-current obtained by applying the value of r of 0 to 0.2 to Equation 5 can maximize this screening effect to increase charge extraction instantly.

The method for driving a solar cell of the present invention may further comprise calculating an error rate c by Equation 6 below, after the stabilization step (S20). The step of calculating an error rate c may be performed when a pulsed-voltage lower than 0 is applied to the electronic device.

ε=100×((Ids−Iout)/(Ids)), [Equation 6]

wherein Iout is a current value output from the solar cell to which the pulsed-voltage is applied, and Ids is a target current value. The target current Ids is a value determined in consideration of driving of the solar cell. For example, the Ids value may be set as the short-circuit current Isc.

The method for driving a solar cell of the present invention may further comprise a pulse re-applying step of terminating the application of the pulsed-voltage or the pulsed-current or changing an application condition for applying the pulsed-voltage or the pulsed-current, based on the error rate ε, after calculating the error rate ε. For example, a pulsed-voltage greater than Voc may be applied to the electronic device when the value of the error rate ε exceeds about 5%.

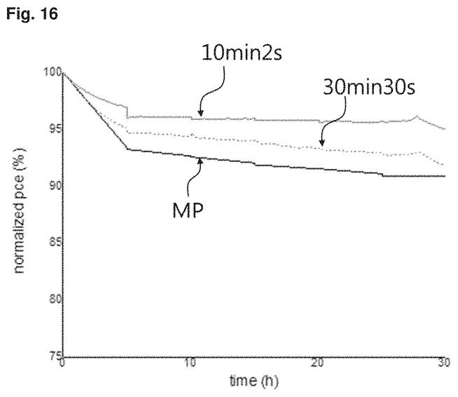

FIG. 16 is a graph showing data obtained by experimenting with ITO/SnO2/(FAI) 0.9 (MABr) 0.1PbI2/Spiro-MeOTAD/Au (Glass encap) device, and shows the efficiency (pce) values as compared with their initial values (normalized pce), for a case (10 min2 s) where after generating electric power for 10 minutes at the maximum power point under 1 sun condition, a reverse pulsed-voltage (V˜−0.2 V) was applied for 2 seconds, a case (30 min30 s) where after generating electric power for 30 minutes at the maximum power point under 1 sun condition, a reverse pulsed-voltage (V˜−0.2 V) was applied for 30 seconds, and a case (MP) of generating electric power at the maximum power point under 1 sun condition without applying any pulse. As shown in FIG. 16, it can be seen that the normalized power over time in the two cases where the pulsed-voltage was applied is greater than that in the case without the application of any pulse, and from this, it can be seen that the stability is improved when the pulse was applied. In addition, through the fact that the condition of applying a 2-second pulse to 10-minute MPPT yields a better effect than the condition of applying a 30-second pulse to 30-minute MPPT, it can be seen that there exist an optimal pulse period (a time interval between pulses) and a pulse duration (duration for one pulse).

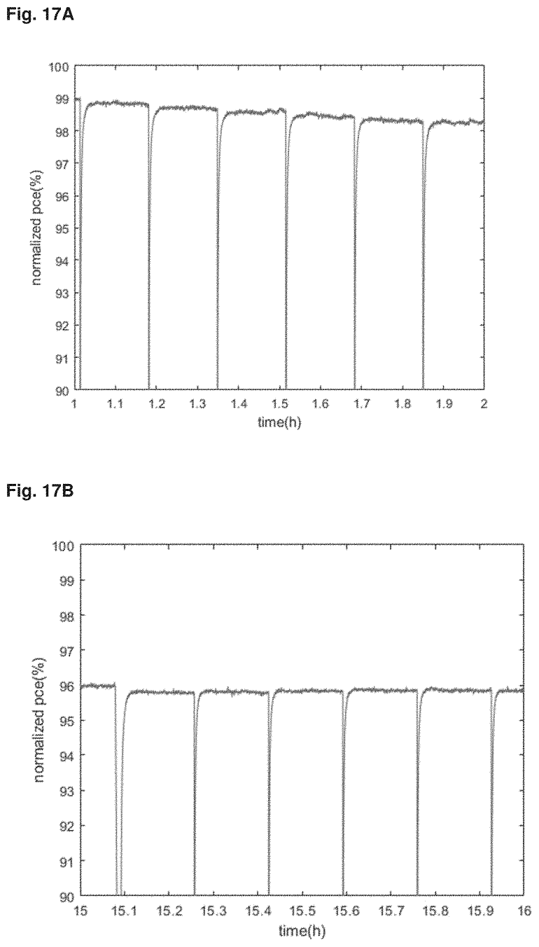

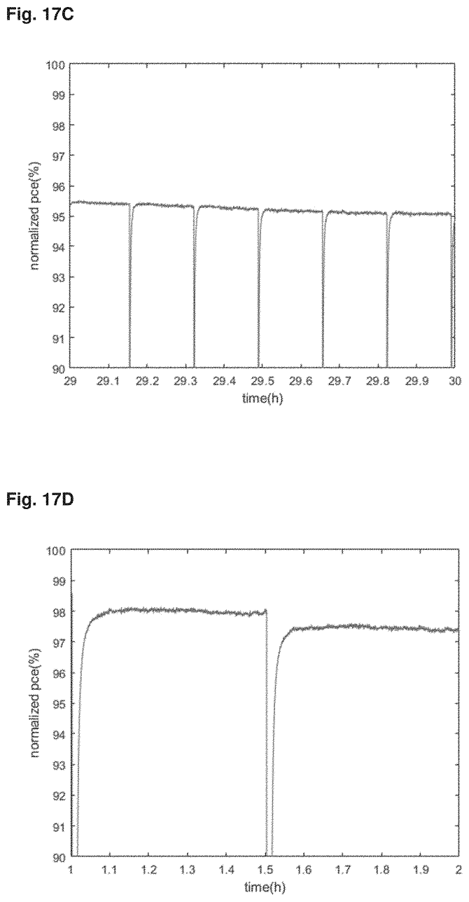

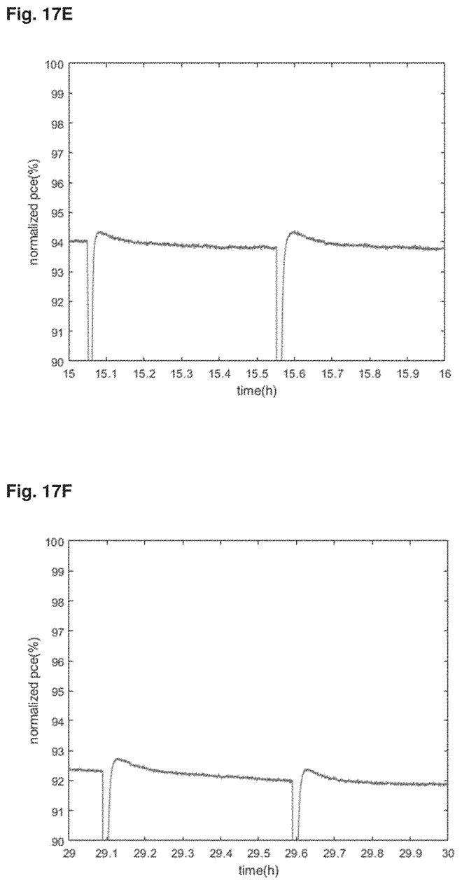

FIGS. 17A to 17F show changes in normalized power before and after applying pulses under the conditions of FIG. 16.

FIG. 17A is a graph showing the change in normalized efficiency before and after applying a pulse for 2 hours under the condition of applying a 2-second pulse to 10-minute MPPT, FIG. 17B is a graph showing the change in normalized efficiency before and after applying a pulse for 16 hours under the condition of applying a 2-second pulse to 10-minute MPPT, FIG. 17C is a graph showing the change in normalized efficiency before and after applying a pulse for 30 hours under the condition of applying a 2-second pulse to 10-minute MPPT, FIG. 17D is a graph showing the change in normalized efficiency before and after applying a pulse for 2 hours under the condition of applying a 30-second pulse to 30-minute MPPT, FIG. 17E is a graph showing the change in normalized efficiency before and after applying a pulse for 16 hours under the condition of applying a 30-second pulse to 30-minute MPPT, and FIG. 17F a graph showing the change in normalized efficiency before and after applying a pulse for 30 hours under the condition of applying a 30-second pulse to 30-minute MPPT.

Although the change in normalized power before and after applying a pulse is not detectable in the case of applying a 2-second pulse to 10-minute MPPT in FIGS. 17A to 17C, it can be seen that in the case of applying a 30-second pulse to 30-minute MPPT in FIGS. 17D to 17F the normalized power over time after applying a pulse becomes larger than that before applying the pulse. In this case, it can be seen that the pulse restores the decreased performance back, which may be an effect of de-trapping trapped charges by applying a pulse, and of repairing the defects associated with ions generated in the perovskite solar cell over time. The fact that there is no change in the value of the normalized power over time before and after applying the pulse in FIGS. 17A to 17C, can be explained by that the condition of applying a 2-second pulse to 10-minute MPPT effectively makes trapped charges to be detrapped, thereby delaying the generation of defects that could have occurred in the perovskite solar cell over time.

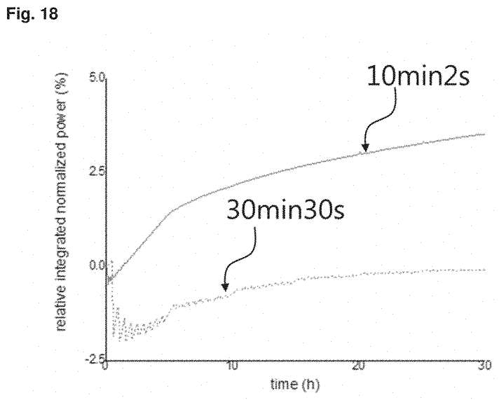

FIG. 18 is a graph in which the total transfer energy under the two application conditions in FIG. 16 is normalized and compared with the transfer energy by the MPPT method. Relative integrated normalized power (%) is calculated through comparison with the normalized work under the MPPT condition, each of which can be defined as in Equations 7 and 8 below.

$$\begin{matrix}Normalized work = {\int }_{0}^{t} {dt}^{′} \frac{pce ( {t}^{′} )}{p c e ( 0 )} , ( [ 0 , t ] ∋ pulse duration ) & [ Equation 7 ] \\ Relative integrated normalized power ( \% ) = 100 \times \frac{\begin{matrix}Normalized work under \\ pulse application condition\end{matrix} }{Normalized work under MPPT condition} - 1 & [ Equation 8 ]\end{matrix}$$

FIG. 18 shows how much the value obtained by dividing the total transfer energy, which even took into account the power loss caused when a pulse was applied, by the initial efficiency increased in % (relative integrated normalized power), as compared to the value obtained by dividing the total transfer energy by the initial efficiency when no pulse was applied. In the case of applying a 2-second pulse to 10-minute MPPT, power gain occurs after 1.5 hours onward, whereas it can be seen that there is no power gain within the experimental time when taking into account the power loss during the pulse, for the case of applying a 30-second pulse to 30-minute MPPT. This indicates that power gain can be maximized by optimizing the pulse period and pulse duration.

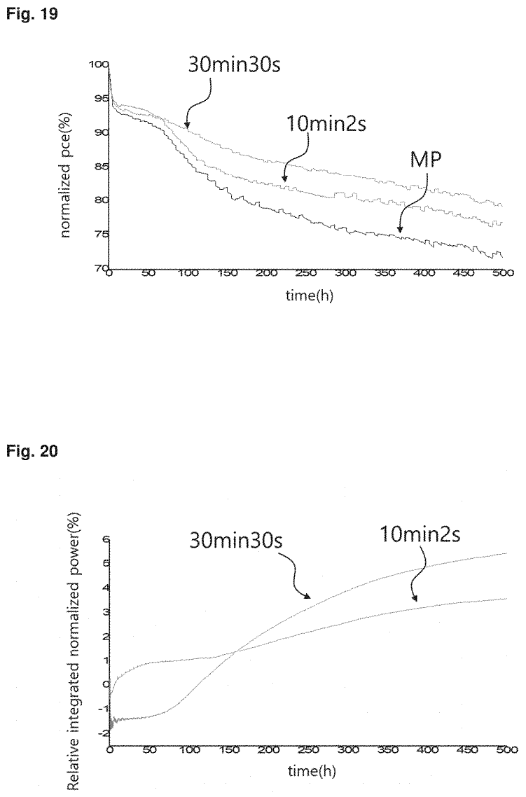

FIG. 19 is a graph showing experimental data with ITO/SnO2/(FAI)0.9(MABr)0.1PbI2/Spiro-MeOTAD/Au (Glass encap) device, and shows the efficiency (pce) values as compared with their initial values (normalized pce), for a case (10 min2 s) where after generating electric power for 10 minutes at the maximum power point under 1 sun condition, a reverse pulsed-voltage (V˜−0.2 V) was applied for 2 seconds, a case (30 min30 s) where after generating electric power for 30 minutes at the maximum power point under 1 sun condition, a reverse pulsed-voltage (V˜−0.2 V) was applied for 30 seconds, and a case (MP) of generating electric power at the maximum power point under 1 sun condition without applying any pulse. As shown in FIG. 19, it can be seen that the normalized power over time in the two cases where the pulsed-voltage was applied is greater than that in the case without the application of any pulse, and from this, it can be seen that the stability is improved when the pulse was applied. In addition, through the fact that the condition of applying a 2-second pulse to 10-minute MPPT yields a better effect than the condition of applying a 30-second pulse to 30-minute MPPT, but not afterward, it can be seen that there exists an appropriate application condition vary according to the time period.

FIG. 20 is a graph in which the total transfer energy under the two application conditions of FIG. 19 is normalized and compared with the transfer energy by the MPPT method. It can be seen that in the case of applying a 2-second pulse to 10-minute MPPT, power gain occurs after 1.5 hours onward, whereas in the case of applying a 30-second pulse to 30-minute MPPT, power gain occurs after 100 hours onward considering the power loss during the pulse, and the power gain is greater than that in the case of applying a 2-second pulse to 10-minute MPPT after 150 hours onward. This indicates that the application conditions to maximize the power gain vary according to the time period.

In the method for driving an electronic device of the present invention, the applying a pulsed-voltage or a pulsed-current to the electronic device may comprise a first pulse applying step of applying a pulsed-voltage or a pulsed-current under a first application condition; and a second pulse applying step of applying a pulsed-voltage or a pulsed-current under a second application condition after the first pulse applying step. That is, a pulsed-voltage or a pulsed-current may be applied to the electronic device under different application conditions for each time period. The application condition may include a pulse time interval, a pulse duration, a pulsed-voltage value, a pulsed-current value, and so on. For example, after the first pulse applying step is performed for 65 hours with a pulse time interval of 10 minutes and a pulse duration of 2 seconds, the second pulse applying step is performed with a pulse time interval of 30 minutes and a pulse duration of 30 seconds.

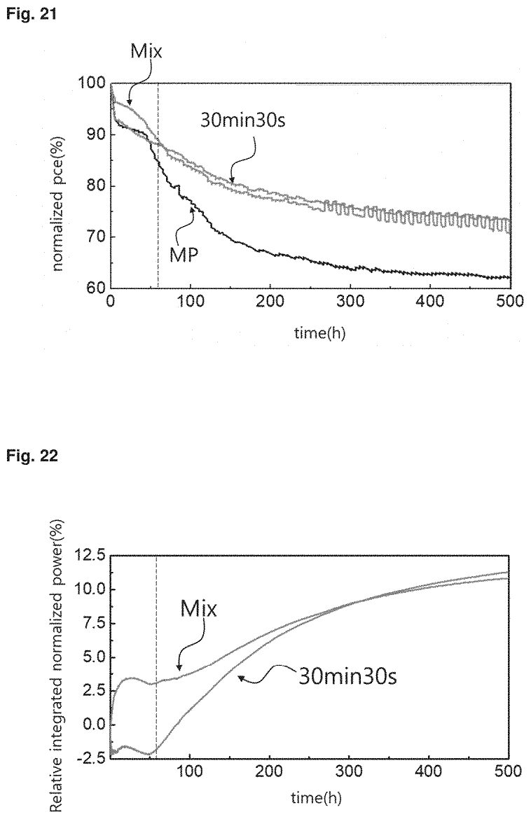

FIG. 21 is a graph showing experimental data with ITO/SnO2/(FAI)0.9(MABr)0.1PbI2/Spiro-MeOTAD/Au (Glass encap) device, and shows the efficiency (pce) values as compared with their initial values (normalized pce), for a case (mixed condition; Mix) where after generating electric power for 10 minutes at the maximum power point under 1 sun condition, a reverse pulsed-voltage (V˜−0.2 V) was applied for 2 seconds until 65 hours (dotted line), and after 65 hours onward, after generating electric power for 30 minutes at the maximum power point under 1 sun condition, a reverse pulsed-voltage (V˜−0.2 V) was applied for 30 seconds, a case (30 min30 s) where after generating electric power for 30 minutes at the maximum power point under 1 sun condition, a reverse pulsed-voltage (V˜−0.2 V) was applied for 30 seconds, and a case (MP) of generating electric power at the maximum power point under 1 sun condition without applying any pulse. As can be seen from FIG. 21, it can be seen that the normalized power over time in the two cases where the pulsed-voltage was applied is greater than that in the case without the application of any pulse, and from this, it can be seen that the stability is improved when the pulse was applied. In addition, through the fact that the slope of the normalized power after changing the condition in the mixed condition is similar to the slope under the condition of applying a 30-second pulse to 30-minute MPPT, it can be seen that even if the pulse condition is changed according to the time period, the effect of improving the stability of the pulse condition corresponding to each time period can be exhibited. In FIG. 21, the dotted line indicates the time point of changing the condition in the mixed condition of pulse.

FIG. 22 is a graph in which the total transfer energy under the two application conditions of FIG. 21 is normalized and compared with the transfer energy by the MPPT method. The power gain after 500 hours is similar between the case (Mix) of mixed condition of applying a 2-second pulse to 30-minute MPPT and applying a 30-second pulse to 30-minute MPPT and the case (30 min30 s) of applying a 30-second pulse to 30-minute MPPT. However, in the case of mixed condition, power gain occurs after 1.5 hours onward, whereas in the case of applying a 30-second pulse to 30-minute MPPT, power gain occurs after 100 hours onward considering the power loss during the pulse. This indicates that the power gain can be maximized by mixing different application conditions according to time period.

As other embodiment, in the stabilization step (S20) of the method for driving a solar cell of the present invention, the stabilization voltage or the stabilization current may be applied as a load voltage or a load current. The stabilization step may comprise a characteristic information obtaining step of obtaining one or more of Isc, Rsh, Rs, i0, mkbT, Voc, Imax, Vmax, Pmax, FF, and Eff as characteristic information of the solar cell; a load value calculating step of calculating a load voltage value or a load current value based on the characteristic information; and a load applying step of applying the load voltage or the load current with the load voltage value or the load current value. If the pulsed-voltage and pulsed-current is to repeatedly apply an instantaneous signal to the solar cell, the load voltage and the load current may be to continuously transforming the transfer voltage while the solar cell is driven. For example, the load voltage may be applied to the solar cell at a constant value as the transfer voltage while the solar cell is driven.

In the load applying step, a load voltage may be applied to the solar cell. When a load voltage may be applied to the solar cell in the load applying step, in the characteristic information obtaining step a current-voltage characteristic curve for the solar cell may be obtained, and in the load value calculating step a reference current value may be calculated by Equation 4 above and a voltage value corresponding to the reference current value on the current-voltage characteristic curve may be used as the load voltage value.

The r value for the load voltage may be a constant of −1 to −0.92.

In the load applying step, a load current may be applied to the solar cell. When a load current may be applied to the solar cell in the load applying step, the load current may be calculated by Equation 9 below.

Iw=Isc×r, [Equation 9]

wherein Iw is a load current, r is a constant of −1 to −0.92, and Isc is a short-circuit current of the solar cell.

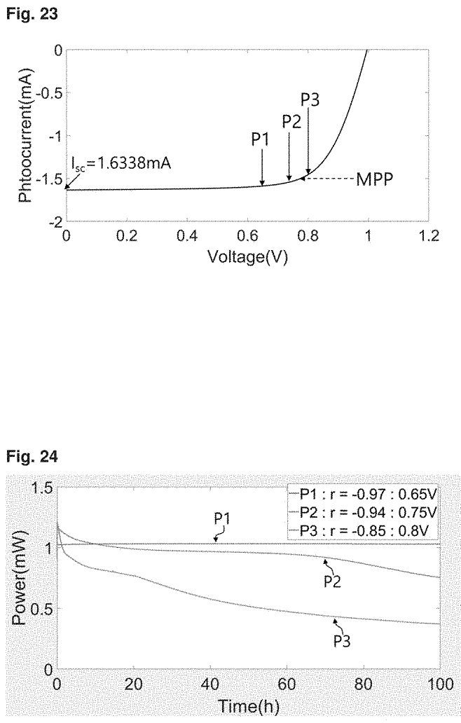

FIG. 23 is a graph showing a current-voltage characteristic curve obtained in a characteristic information obtaining step when a load voltage is applied to a solar cell in a load applying step.

In FIG. 23, the first point P1 in which r is −0.9718 (˜−0.97), the second point P2 in which r is −0.9371 (˜−0.94), and the third point P3 in which r is −0.8526 (˜−0.85) are indicated on the current-voltage characteristic curve. Based on Equation 4, the load voltage at the first point P1 was calculated as 0.65, the load voltage at the second point P2 was calculated as 0.75, and the load voltage at the third point P3 was calculated as 0.8. For reference, the current value at the maximum power point (MPP) is about −0.9 times the short-circuit current value.

FIG. 24 is a graph showing a transfer power for each of two solar cells to which load voltages are applied at three points P1, P2, and P3 shown in FIG. 23, respectively. It can be seen that since the load voltage at the first point P1 is smaller than the transfer voltage at the maximum power point, the power is not the maximum, but the stability is excellent.

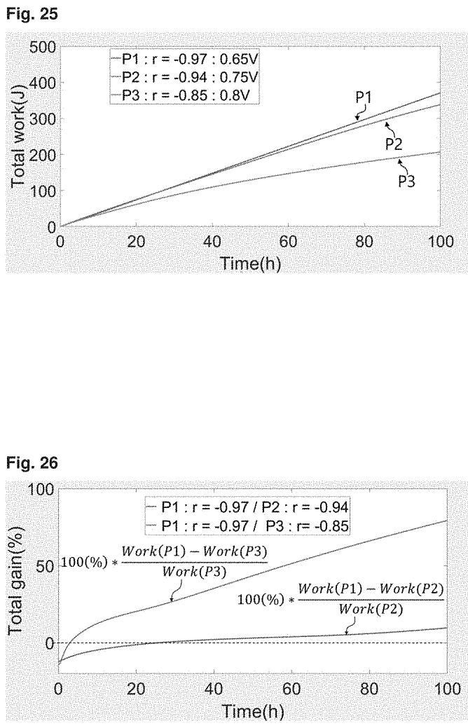

FIG. 25 is a graph showing a total work for each of two solar cells to which load voltages are applied at three points P1, P2, and P3 shown in FIG. 23, respectively. It can be seen that it is more excellent in terms of a total work when the load voltage of the first point P1 is applied due to stable driving.

FIG. 26 is a graph showing a total gain obtained by comparing total works of three solar cells to which load voltages are applied at three points P1, P2, and P3 shown in FIG. 23, respectively. Comparing the total work when the load voltage is applied at the first point P1 to that when the load voltage is applied at the second point P2, the total work when the load voltage is applied at the first point P1 is smaller until about 30 hours due to the smaller initial power, whereas the total work becomes greater as the solar cell is driven for 30 hours or longer, because of superior stability. Similarly, comparing the total work when the load voltage is applied at the first point P1 to that when the load voltage is applied at the third point P3, the total work when the load voltage is applied at the first point P1 is smaller until about 5 hours due to the smaller initial power, whereas the total work is greater as the solar cell is driven for 5 hours or longer, because of superior stability.

As other embodiment, in the stabilization step (S20) of the method for driving a solar cell of the present invention, the stabilization voltage or the stabilization current may be applied as a pulsed-voltage or a pulsed-current. The stabilization step may comprise a characteristic information obtaining step of obtaining characteristic information of the solar cell; a pulse value calculating step of calculating a pulsed-voltage value or a pulsed-current value based on the characteristic information; and a pulse applying step of applying the pulsed-voltage or the pulsed-current with the pulsed-voltage value or the pulsed-current value, and the characteristic information obtaining step may be performed during driving of the solar cell and the pulse applying step may be performed after the driving of the solar cell is terminated.

That is, a pulsed-voltage or pulsed-current may be applied to the solar cell in a state in which the transfer voltage is 0 V and a photocurrent of 0 A flows. The pulsed-voltage and pulsed-current can be selected based on the current-voltage characteristic curve measured lastly during driving. In this case, the pulsed-voltage or pulsed-current may be calculated by any one of Equations 1 to 5.

The pulsed-voltage calculated in the method as described above can be more effective when applied to solar cells used in concentrator photovoltaic systems. Of the photovoltaic methods, in the case of a concentrator photovoltaic panel that collects incident light from the sun and produces high output even with a small area, it is known that the number of electrons and holes generated inside a device is much higher because the light of strong intensity is incident, and thus, the performance degradation is faster. If the method for driving an electronic device of the present invention is applied to such a concentrator photovoltaic system, electrons and holes accumulated inside the electronic device can be effectively extracted.

A concentrator solar cell in a concentrator photovoltaic panel may be coupled with a concentration means for focusing light. The concentration means may be an optical device that focuses light, such as a lens and a reflector.

Although the power supply source 100 has been described as one embodiment as an example of the present invention, the present invention is not limited to what has been described above, and various modifications, changes, and applications are possible according to diverse conditions and environments in which the present invention is implemented, such as that can be implemented in a method of applying a pulsed-voltage while driving an organic thin-film transistor (OTFT), an organic light-emitting diode (OLED), an organic sensor, an organic memory device and so on.

It will be appreciated that the technical configurations of the present invention described above can be implemented in other specific forms by those having ordinary skill in the art to which the present invention pertains, without changing the spirit or essential features of the present invention. Therefore, it should be understood that the embodiments described above are exemplary in all aspects and are not as not limiting. In addition, the scope of the invention is indicated by the claims that follow, rather than by the detailed description above. Furthermore, all modifications or variations derived from the meaning and scope of the claims and their equivalent concepts should be construed as being included in the scope of the present invention.

1. A method for driving a solar cell comprising:
a driving step in which the solar cell is driven as a power supply source for generating power by exposure while a transfer voltage is applied; and
a stabilization step of stabilizing a driving state of the solar cell by controlling the current flowing through the solar cell with a stabilization current or controlling the transfer voltage with a stabilization voltage.

2. The method for driving a solar cell according to claim 1, wherein the stabilization step is performed during driving of the solar cell, and
in the stabilization step,
the stabilization voltage or the stabilization current is applied as a pulsed-voltage or a pulsed-current.

3. The method for driving a solar cell according to claim 2, wherein the pulsed-voltage or the pulsed-current is a pulse signal comprising at least one selected from the group consisting of steps, ramps, sine waves, and signals generated through operations thereof.

4. The method for driving a solar cell according to claim 3, wherein in the stabilization step,
the pulsed-voltage or the pulsed-current is applied under a predetermined application condition, and
the application condition comprises one or more of a pulse time interval, a pulse duration, a pulsed-voltage value, a pulsed-current value, and the number of pulse.

5. The method for driving a solar cell according to claim 4, wherein the stabilization step comprises:
a first pulse applying step of applying a pulsed-voltage or a pulsed-current under a first application condition; and
a second pulse applying step of applying a pulsed-voltage or a pulsed-current under a second application condition after the first pulse applying step.

6. The method for driving a solar cell according to claim 4, wherein the stabilization step comprises:
a characteristic information obtaining step of obtaining one or more of Isc, Rsh, Rs, i0, mkbT, Voc, Imax, Vmax, Pmax, FF, and Eff as characteristic information of the solar cell;
a pulse value calculating step of calculating a pulsed-voltage value or a pulsed-current value based on the characteristic information; and
a pulse applying step of applying the pulsed-voltage or the pulsed-current with the pulsed-voltage value or the pulsed-current value.

7. The method for driving a solar cell according to claim 6, wherein:
in the pulse applying step the pulsed-voltage is applied to the solar cell, and
in the pulse value calculating step the pulsed-voltage is calculated by Equation 1 below:
Vp=−r×Isc×Rs, [Equation 1]
wherein Vp is a pulsed-voltage, r is a constant of 0.9 to 2, Isc is a short circuit-current of the solar cell, and Rs is a series resistance of the solar cell.

8. The method for driving a solar cell according to claim 6, wherein:
in the pulse applying step the pulsed-voltage is applied to the solar cell, and
in the pulse value calculating step the pulsed-voltage is calculated by Equation 2 below:
Vp=−r×Voc, [Equation 2]
wherein Vp is a pulsed-voltage, r is a constant of 0.1 to 0.3, and Voc is an open-circuit voltage of the solar cell.

9. The method for driving a solar cell according to claim 6, wherein:
in the pulse applying step the pulsed-voltage is applied to the solar cell, and
in the pulse value calculating step the pulsed-voltage is calculated by Equation 3 below:
Vp=r×Voc, [Equation 3]
wherein Vp is a pulsed-voltage, r is a constant of 1 to 1.2, and Voc is an open-circuit voltage of the solar cell.

10. The method for driving a solar cell according to claim 6, wherein:
in the pulse applying step the pulsed-voltage is applied to the solar cell,
in the characteristic information obtaining step a current-voltage characteristic curve for the solar cell is obtained, and
in the pulse value calculating step a reference current value is calculated by Equation 4 below and a voltage value corresponding to the reference current value on the current-voltage characteristic curve is calculated as the pulsed-voltage value:
Icr=Isc×r, [Equation 4]
wherein Icr is a reference current, r is a constant of −1 to −0.92 or 0 to 0.2, and Isc is a short-circuit current of the solar cell.

11. The method for driving a solar cell according to claim 6, wherein:
in the pulse applying step the pulsed-current is applied to the solar cell, and
the pulsed-current is calculated by Equation 5 below:
Ip=Isc×r, [Equation 5]
wherein Ip is a pulsed-current, r is a constant of −1 to −0.92 or 0 to 0.2, and Isc is a short-circuit current of the solar cell.

12. The method for driving a solar cell according to claim 2, further comprising calculating an error rate ε by Equation 6 below, after the stabilization step:
ε=100×((Ids−Iout)/(Ids)), [Equation 6]
wherein Iout is a current value output from the solar cell to which the pulsed-voltage is applied, and Ids is a target current value.

13. The method for driving a solar cell according to claim 12, further comprising a pulse re-applying step of terminating the application of the pulsed-voltage or the pulsed-current or changing an application condition for applying the pulsed-voltage or the pulsed-current, based on the error rate ε.

14. The method for driving a solar cell according to claim 1, wherein:
the stabilization step is performed during driving of the solar cell,
in the stabilization step,
the stabilization voltage or the stabilization current is applied as a load voltage or a load current, and
the stabilization step comprises:
a characteristic information obtaining step of obtaining one or more of Isc, Rsh, Rs, i0, mkbT, Voc, Imax, Vmax, Pmax, FF, and Eff as characteristic information of the solar cell;
a load value calculating step of calculating a load voltage value or a load current value based on the characteristic information; and
a load applying step of applying the load voltage or the load current with the load voltage value or the load current value.

15. The method for driving a solar cell according to claim 14, wherein:
in the load applying step the load voltage is applied to the solar cell,
in the characteristic information obtaining step a current-voltage characteristic curve for the solar cell is obtained, and
in the load value calculating step a reference current value is calculated by Equation 4 below and a voltage value corresponding to the reference current value on the current-voltage characteristic curve is calculated as the pulsed-voltage value:
Icr=Isc×r, [Equation 4]
wherein Icr is a reference current, r is a constant of −1 to −0.92, and Isc is a short-circuit current of the solar cell.

16. The method for driving a solar cell according to claim 14, wherein in the load applying step the load current is applied to the solar cell, and the load current is calculated by Equation 9 below:
Iw=Isc×r, [Equation 9]
wherein Iw is a load current, r is a constant of −1 to −0.92, and Isc is a short-circuit current of the solar cell.

17. The method for driving a solar cell according to claim 1, wherein:
in the stabilization step the stabilization voltage or the stabilization current is applied as a pulsed-voltage or a pulsed-current,
the stabilization step comprises:
a characteristic information obtaining step of obtaining characteristic information of the solar cell;
a pulse value calculating step of calculating a pulsed-voltage value or a pulsed-current value based on the characteristic information; and
a pulse applying step of applying the pulsed-voltage or the pulsed-current with the pulsed-voltage value or the pulsed-current value, and
the characteristic information obtaining step is performed during driving of the solar cell and the pulse applying step is performed after the driving of the solar cell is terminated.
